(19) United States
(12) Patent Application Publication
(10) Pub. No.: US 2023/0009353 A1
(43) Pub. Date: Jan. 12, 2023

(54) DISPLAY DEVICE

(71) Applicant: Samsung Display Co., LTD., Yongin-si (KR)

(72) Inventors: Young Wan SEO, Suwon-si (KR); Kyung Hoe LEE, Hwaseong-si (KR); Ja Eun LEE, Suwon-si (KR); Ji-Sun KIM, Seoul (KR); Keun Hee CHOI, Hwaseong-si (KR)

(73) Assignee: Samsung Display Co., LTD., Yongin-si (KR)

(21) Appl. No.: 17/857,638

(22) Filed: Jul. 5, 2022

(30) Foreign Application Priority Data
Jul. 8, 2021 (KR) 10-2021-0089535

(51) Int. Cl. H01L 27/32

(52) U.S. Cl. CPC H01L 27/3218; H01L 27/3262; H01L 27/124

(57) ABSTRACT

A display device includes a display area including a first display area and a second display area; a first pixel circuit; a first light emitting element; a second pixel circuit; second light emitting elements; and a driving circuit overlapping the second light emitting elements in a plan view, wherein an edge of the display area includes a straight portion and a round portion, the second light emitting elements that are near each other in a first direction and a second direction configure a light emitting element group, and a number of the second light emitting elements configuring the light emitting element group disposed on the round portion is different from a number of the second light emitting elements configuring the light emitting element group disposed on the straight portion.

### CROSS-REFERENCE TO RELATED APPLICATION(S)

This application claims priority to and the benefit of Korean Patent Application No. 10-2021-0089535 under 35 U.S.C. § 119, filed in the Korean Intellectual Property Office (KIPO) on Jul. 8, 2021, the entire contents of which are incorporated herein by reference.

### BACKGROUND

### 1. Technical Field

The disclosure relates to a display device with an expanded display area having a round portion of a soft curved edge.

### 2. Description of the Related Art

A display device displays images on a screen, and it may be a liquid crystal display (LCD) and an organic light emitting diode display (OLED). The display device is used to various electronic devices such as portable phones, GPS, digital cameras, electronic books, portable game devices, or various terminals.

The display device may include a display area for displaying a screen and a peripheral area, in which an image is not displayed. Pixels may be disposed (or arranged) in a row direction and a column direction in the display area. Various elements such as transistors or capacitors and various wires for supplying signals to the elements may be positioned in each of the pixels. Various wires for transmitting electrical signals for driving the pixels, a scan driver, a data driver, and a controller may be positioned in the peripheral area.

Demands to reduce a size of the peripheral area and enlarge the display area are increasing, but an area occupied by the driver increases in a process for realizing high resolution and high-rate driving, so it is difficult to reduce the size of the peripheral area.

The above information disclosed in this Background section is only for enhancement of understanding of the background of the described technology, and therefore it may contain information that does not form the prior art that is already known in this country to a person of ordinary skill in the art.

### SUMMARY

The described technology has been made in an effort to provide a display device with an expanded display area.

The described technology has been made in another effort to provide a display device with an expanded display area having a round portion of a soft curved edge.

An embodiment provides a display device including: a display area including a first display area and a second display area; a first pixel circuit disposed in the first display area; a first light emitting element electrically connected to the first pixel circuit; a second pixel circuit disposed in the second display area; second light emitting elements electrically connected to the second pixel circuit; and a driving circuit electrically connected to the first pixel circuit and the second pixel circuit and overlapping the second light emitting elements in a plan view, wherein an edge of the display area includes a straight portion and a round portion, the second light emitting elements that are near each other in a first direction and a second direction that is perpendicular to the first direction configure a light emitting element group, and a number of the second light emitting elements configuring the light emitting device group disposed on the round portion is different from a number of the second light emitting elements configuring the light emitting element group disposed on the straight portion.

The second light emitting element may include a first sub-light emitting element that emits a first color; a second sub-light emitting element that emits a second color; and a third sub-light emitting element and a fourth sub-light emitting element that emits a third color.

The first color may be red, the second color may be blue, and the third color may be green.

The light emitting element group may include first sub-light emitting elements, second sub-light emitting elements, third sub-light emitting elements, and fourth sub-light emitting elements.

The first sub-light emitting elements disposed in the light emitting element group may be electrically connected to each other, the second sub-light emitting elements disposed in the light emitting element group may be electrically connected to each other, and the third sub-light emitting elements disposed in the light emitting element group may be electrically connected to each other, and the fourth sub-light emitting elements disposed in the light emitting element group may be electrically connected to each other.

The number of the second light emitting elements configuring the light emitting element group disposed on the round portion may be smaller than the number of the second light emitting elements configuring the light emitting element group disposed on the straight portion.

The number of the second light emitting elements configuring the light emitting element group disposed on the straight portion may be sixteen, and the number of the second light emitting elements configuring the light emitting element group disposed on the round portion may be twelve.

The light emitting element group disposed on the straight portion may include four first sub-light emitting elements, four second sub-light emitting elements, four third sub-light emitting elements, and four fourth sub-light emitting elements.

The light emitting element group disposed on the round portion may include three first sub-light emitting elements, three second sub-light emitting elements, two third sub-light emitting elements, and four fourth sub-light emitting elements.

The light emitting element group disposed on the round portion may include three first sub-light emitting elements, three second sub-light emitting elements, three third sub-light emitting elements, and three fourth sub-light emitting elements.

The number of the second light emitting elements configuring the light emitting element group disposed on the round portion may be greater than the number of the second light emitting elements configuring the light emitting element group disposed on the straight portion.

The number of the second light emitting elements configuring the light emitting element group disposed on the straight portion may be sixteen, and the number of the second light emitting elements configuring the light emitting element group disposed on the round portion may be twenty.

The light emitting element group disposed on the straight portion may include four first sub-light emitting elements, four second sub-light emitting elements, four third sub-light emitting elements, and four fourth sub-light emitting elements.

The light emitting element group disposed on the round portion may include five first sub-light emitting elements, five second sub-light emitting elements, four third sub-light emitting elements, and six fourth sub-light emitting elements.

The light emitting element group disposed on the round portion may include five first sub-light emitting elements, five second sub-light emitting elements, five third sub-light emitting elements, and five fourth sub-light emitting elements.

The first sub-light emitting elements disposed in the light emitting element group may have a same luminance, the second sub-light emitting elements disposed in the light emitting element group may have a same luminance, the third sub-light emitting elements disposed in the light emitting element group may have the same luminance, and the fourth sub-light emitting elements disposed in the light emitting element group may have a same luminance.

The number of the second light emitting elements configuring the light emitting element group disposed on the round portion may be different from the number of the second light emitting elements configuring the light emitting element group disposed further inside than the light emitting element group disposed on the round portion.

The number of the second light emitting elements configuring the light emitting element group disposed on the round portion may be greater than the number of the second light emitting elements configuring the light emitting element group disposed further inside than the light emitting element group disposed on the round portion.

The display device may further include a peripheral area surrounding the display area that displays an image. The display area may include the first display area and the second display area. The second display area may be disposed between the first display area and the peripheral area.

Part of the driving circuit may be disposed in the second display area, and other part of the driving circuit may be disposed in the peripheral area.

According to the embodiments, the display device with the enlarged display area may be provided. For example, the display area of the display device may be increased.

Further, in the display device of the embodiments, the round portion of the edge of the display area may have a soft (or smooth) curved line shape. Thus, the luminance of the edge of the display area may be adjusted (e.g., decreased), and the visibility and image display quality of the display device may be provided.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 shows a schematic plan view of a display device according to an embodiment,

FIG. 2 shows a schematic cross-sectional view with respect to line II-II of FIG. 1,

FIG. 3 shows a schematic cross-sectional view of a part of a display device according to an embodiment,

FIG. 4 shows a schematic cross-sectional view of an enlarged part of a layer of a region of FIG. 3,

FIGS. 5 and 6 show schematic circuit diagrams of pixels of display devices according to embodiments,

FIGS. 7 to 9 show schematic views of arrangements of second light emitting devices of display devices according to embodiments,

FIGS. 10 and 11 show schematic views of arrangements of second light emitting devices of display devices according to embodiments,

FIG. 12 shows a schematic diagram of an arrangement of a second light emitting device of a display device according to an embodiment,

FIG. 13 shows a schematic diagram of an arrangement of a second light emitting device of a display device according to an embodiment, and

FIG. 14 shows a schematic diagram of an arrangement of a second light emitting device of a display device according to an embodiment.

### DETAILED DESCRIPTION OF THE EMBODIMENTS

The disclosure will be described more fully hereinafter with reference to the accompanying drawings, in which embodiments of the invention are shown. As those skilled in the art would realize, the described embodiments may be modified in various different ways, all without departing from the spirit or scope of the disclosure.

Parts that are irrelevant to the description may be omitted to clearly describe the disclosure, and the same elements will be denoted by the same reference numerals throughout the specification.

The size and thickness of each configuration shown in the drawings are arbitrarily shown for better understanding and ease of description, but the disclosure is not limited thereto. In the drawings, the thickness of layers, films, panels, regions, etc., may be enlarged for clarity. The thicknesses of some layers and areas may be exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

Unless explicitly described to the contrary, the word “comprise”, and variations such as “comprises” or “comprising” will be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

It will be understood that the terms “contact,” “connected to,” and “coupled to” may include a physical and/or electrical contact, connection, or coupling, and vice versa.

The phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

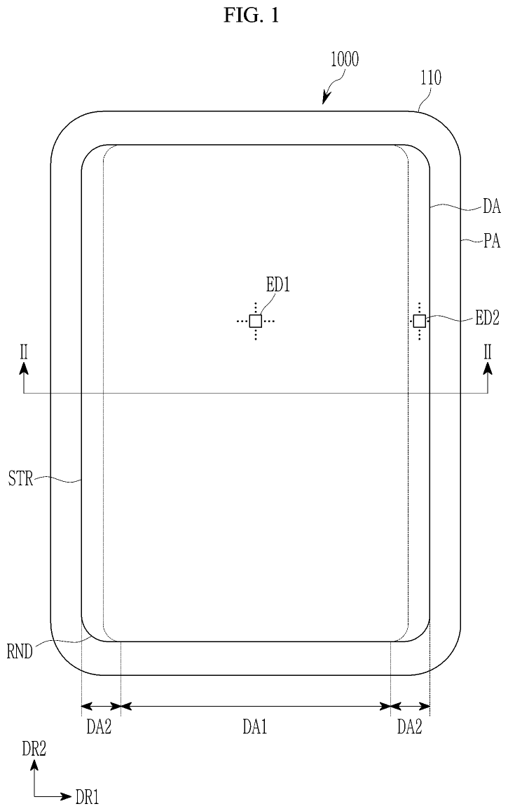

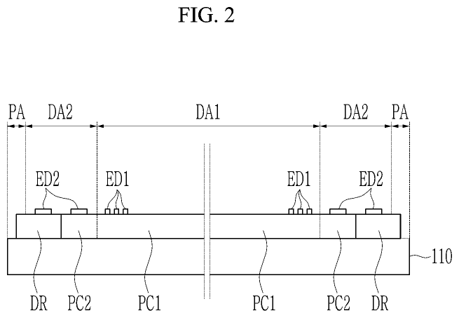

A display device according to an embodiment is provided below with reference to FIGS. 1 and 2.

FIG. 1 shows a schematic plan view of a display device according to an embodiment, and FIG. 2 shows a schematic cross-sectional view with respect to line II-II of FIG. 1.

As shown in FIGS. 1 and 2, the display device 1000 may include a substrate 110 and light emitting devices (or light emitting elements) ED1 and ED2 positioned on the substrate 110.

The substrate 110 may include a display area DA and a peripheral area PA positioned near (or adjacent to) the display area DA.

The display area DA may be positioned at a center of the display device 1000. The display area DA may have a quadrangular shape, and each of corners of the display area DA may have a round shape. For example, an edge of the display area DA may include a straight portion STR in a straight shape and a round portion RND in a round shape. The shape of the display area DA and the shape of the corner are not limited thereto, and may be changeable in various ways. The display area DA may include a first display area DA1 and a second display area DA2 positioned near (or adjacent to) the first display area DA1. The first display area DA1 may be positioned at a center of the display area DA, and the second display area DA2 may be positioned on each of sides of the display area DA. For example, the second display area DA2 may be disposed on a right and a left of the first display area DA1. However, positions of the first display area DA1 and the second display area DA2 are not limited thereto, and may be changeable in various ways. For example, the first display area DA1 may have a quadrangular shape, and the second display area DA2 may surround four corners of the first display area DA1. For example, the second display area DA2 may be positioned on right, left, top, and bottom of the first display area DA1.

The peripheral area PA may surround the display area DA. The peripheral area PA may not display an image, and the peripheral area PA may be positioned on an outside of the display device 1000.

At least part of the display device 1000 according to an embodiment may include a bending portion. For example, the center of the display device 1000 may be flat, and an edge of the display device 1000 may have a bent shape. At least part of the second display area DA2 may be positioned on the bending portion. For example, at least part of the second display area DA2 of the substrate 110 may have a bent shape.

The light emitting devices ED1 and ED2 may emit light. For example, the light emitting devices ED1 and ED2 may emit light such as red, green, blue, or white light. The display device 1000 may display images through the light emitted by the light emitting devices ED1 and ED2. The light emitting devices ED1 and ED2 may include a first light emitting device ED1 and a second light emitting device ED2. The light emitting devices ED1 and ED2 may be positioned in the display area DA. The first light emitting device ED1 may be positioned in the first display area DA1, and the second light emitting device ED2 may be positioned in the second display area DA2. Although not shown, the display device 1000 may include multiple first light emitting devices ED1 and multiple second light emitting devices ED2. The first light emitting devices ED1 may be disposed (or arranged) in a first direction DR1 and a second direction DR2, and disposed in the first display area DAL. The second light emitting devices ED2 may be disposed (or arranged) in the first direction DR1 and the second direction DR2, and disposed in the second display area DA2. A size of the first light emitting device ED1 and a size of the second light emitting device ED2 may be equal to or different from each other. For example, the second light emitting device ED2 may be bigger than the first light emitting device ED1. A number of first light emitting devices ED1 per area and a number of second light emitting devices ED2 per area may be equal to or different from each other. For example, the first light emitting devices ED1 in the first display area DA1 and the second light emitting devices ED2 in the second display area DA2 may have a same density of different density from each other. For example, the number of the second light emitting devices ED2 per area may be smaller than the number of the first light emitting devices ED1 per area. For example, the density of the second light emitting devices ED2 in the second display area DA2 may be smaller than the density of the first light emitting devices ED1 in the first display area DA1. A resolution of the first display area DA1 and a resolution of the second display area DA2 may be equal to or different from each other. For example, the resolution of the first display area DA1 may be higher than the resolution of the second display area DA2. The arrangements and the sizes of the first light emitting device ED1 and the second light emitting device ED2, and the resolutions of the first display area DA1 and the second display area DA2 are not limited thereto, and may be modifiable in many ways.

The display device 1000 may further include pixel circuits PC1 and PC2 positioned on the substrate 110. The pixel circuits PC1 and PC2 may include a first pixel circuit PC1 and a second pixel circuit PC2. The display device 1000 may include multiple first pixel circuits PC1 and multiple second pixel circuits PC2. The first pixel circuit PC1 may substantially represent a region (or a circuit) in which multiple first pixel circuits PC1 are disposed (or arranged) in the first direction DR1 and the second direction DR2. The second pixel circuit PC2 may substantially represent a region (or a circuit) in which multiple second pixel circuits PC2 are disposed (or arranged) in the first direction DR1 and the second direction DR2. However, the arrangement of the pixel circuits PC1 and PC2 are not limited thereto, and the pixel circuits PC1 and PC2 may be arranged in various ways. The first pixel circuit PC1 may be positioned in the first display area DA1, and the second pixel circuit PC2 may be positioned in the second display area DA2. Each of the pixel circuits PC1 and PC2 may be electrically connected to at least one of the light emitting devices ED1 and ED2. The first pixel circuit PC1 may be electrically connected to the first light emitting device ED1, and the second pixel circuit PC2 may be electrically connected to the second light emitting device ED2. The second pixel circuit PC2 may be electrically connected to multiple of the second light emitting devices ED2. The size of the first pixel circuit PC1 and the size of the second pixel circuit PC2 may be equal to or different from each other. For example, the second pixel circuit PC2 may be bigger than the first pixel circuit PC1. The first pixel circuit PC1 and the second pixel circuit PC2 may have different structures.

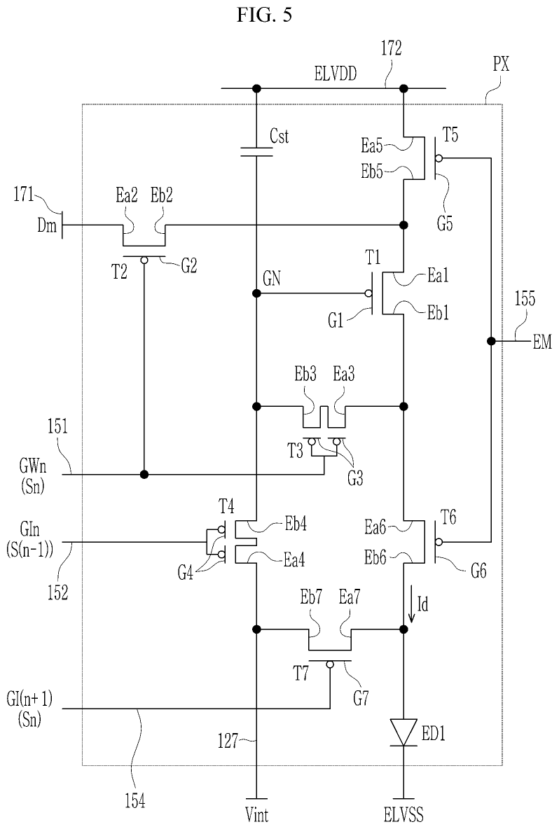

The display device 1000 may further include a driving circuit DR positioned on the substrate 110. The driving circuit DR may be electrically connected to the first pixel circuit PC1 and the second pixel circuit PC2. The driving circuit DR may include drivers and signal wires. For example, the driving circuit DR may include a scan driver, a data driver, a driving voltage supplying line, a common voltage supplying line, and a signal transfer wire electrically connected to at least one of the drivers and the lines. The scan driver may generate scan signals and transmit the scan signals to the pixel circuits PC1 and PC2 through a scan line. The data driver may generate data signals and transmit the data signals to the pixel circuits PC1 and PC2 through a data line 171 (e.g., refer to FIG. 5). The driving voltage supplying line may transmit a driving voltage to the pixel circuits PC1 and PC2. The common voltage supplying line may transmit a common voltage to an electrode of the light emitting devices ED1 and ED2. At least part of the driving circuit DR may be positioned in the second display area DA2, and a remaining portion of the driving circuit DR may be positioned in the peripheral area PA.

The first pixel circuit PC1 may be electrically connected to the first light emitting device ED1 disposed on the first pixel circuit PC1 in the first display area DA1. A light emitting region of the first light emitting device ED1 may overlap the first pixel circuit PC1 electrically connected to the light emitting region in a plan view. The first display area DA1 may emit light by the first light emitting device ED1.

The second pixel circuit PC2 may be electrically connected to the second light emitting device ED2 spaced apart from the second pixel circuit PC2 by an interval in the second display area DA2. The light emitting region of the second light emitting device ED2 may not overlap (or may be spaced apart from) the second pixel circuit PC2 electrically connected to the light emitting region in a plan view. The light emitting region of the second light emitting device ED2 may overlap the second pixel circuit PC2 that is not electrically connected to the light emitting region in a plan view. The light emitting region of the second light emitting device ED2 may overlap the driving circuit DR in a plan view. A portion of the light emitting region of the second light emitting device ED2 may overlap the second pixel circuit PC2 electrically connected to the portion of the light emitting region in a plan view. The second display area DA2 may emit light by the second light emitting device ED2.

In a display device according to another embodiment, a pixel circuit and a light emitting device may be positioned in a display area and may not be positioned in a peripheral area surrounding the display area, and a driving circuit may be positioned in the peripheral area. Therefore, the peripheral area may not emit light and a dead space may be formed in the peripheral area in which the driving circuit is positioned. However, in the display device according to an embodiment, the second light emitting device ED2 may be positioned on the portion on which the driving circuit DR is positioned, and the second light emitting device ED2 may emit light. Thus, the region in which the screen is displayed may be increased. For example, since the second light emitting device ED2 is positioned on the driving circuit DR, the dead space may be reduced and a bezel of the display device 1000 may be reduced.

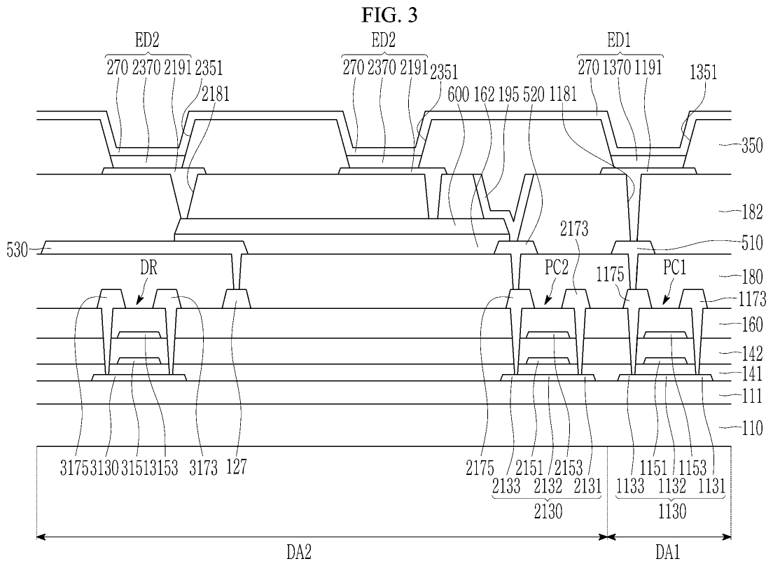

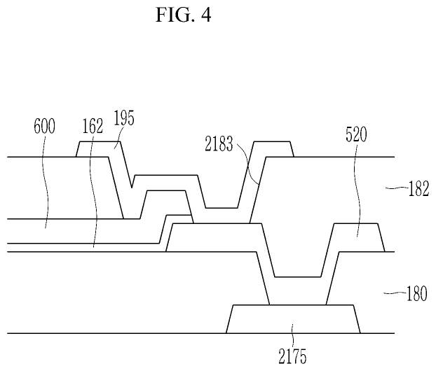

A connection relationship between pixel circuits of a display device and a light emitting device according to an embodiment is provided below with reference to FIGS. 3 and 4.

FIG. 3 shows a schematic cross-sectional view of a part of a display device according to an embodiment, and FIG. 4 shows a schematic cross-sectional view of an enlarged part of a layer of a region of FIG. 3.

Referring to FIG. 3, the light emitting region of the first light emitting device ED1 of the display device according to an embodiment may overlap the first pixel circuit PC1 electrically connected to the first light emitting device ED1 in a plan view.

The first pixel circuit PC1 may include a semiconductor 1130, a gate electrode 1151, a source electrode 1173, and a drain electrode 1175 positioned in the first display area DA1 of the substrate 110.

The substrate 110 may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. The substrate 110 may include a flexible material that may be bent or folded, and the substrate 110 may be single- or multi-layered.

A buffer layer 111 may be positioned on the substrate 110. The buffer layer 111 may have a single- or multi-layered structure. The buffer layer 111 may include an inorganic insulating material such as a silicon nitride (SiNx), a silicon oxide (SiOx), a silicon oxynitride (SiOxNy), or the like, or an organic insulating material. In another embodiment, the buffer layer 111 may be omitted. A barrier layer (not illustrated) may further be positioned between the substrate 110 and the buffer layer 111. The barrier layer (not illustrated) may be a single- or multi-layered structure. The barrier layer (not illustrated) may include an inorganic insulating material such as a silicon nitride (SiNx), a silicon oxide (SiOx), or a silicon oxynitride (SiOxNy).

A semiconductor layer including a semiconductor 1130 of the first pixel circuit PC1 may be positioned on the buffer layer 111. The semiconductor 1130 may include a first region 1131, a channel 1132, and a second region 1133. The first region 1131 and the second region 1133 may be respectively positioned on each of sides of the channel 1132 of the semiconductor 1130 of the first pixel circuit PC1. The semiconductor 1130 of the first pixel circuit PC1 may include a semiconductor material such as amorphous silicon, polysilicon, an oxide semiconductor, or the like.

A first gate insulating layer 141 may be positioned on the semiconductor 1130 of the first pixel circuit PC1. The first gate insulating layer 141 may have a single- or multi-layered structure. The first gate insulating layer 141 may include an inorganic insulating material such as a silicon nitride (SiNx), a silicon oxide (SiOx), a silicon oxynitride (SiOxNy), or the like.

A first gate conductive layer including the gate electrode 1151 of the first pixel circuit PC1 may be positioned on the first gate insulating layer 141. The gate electrode 1151 of the first pixel circuit PC1 may overlap the channel 1132 of the semiconductor 1130 in a plan view. The first gate conductive layer may have a single- or multi-layered structure. The first gate conductive layer may include a metallic material such as molybdenum (Mo), aluminum (Al), copper (Cu), titanium (Ti), or an alloy thereof. After the first gate conductive layer is formed, a doping process or a plasma process may be performed on the first gate conductive layer. A portion of the semiconductor layer covered by the first gate conductive layer may not be doped or plasma-processed, and another portion of the semiconductor layer, which is not covered by the first gate conductive layer, may be doped or plasma-processed to have same electric characteristics as a conductor.

A second gate insulating layer 142 may be positioned on the first gate conductive layer including the gate electrode 1151 of the first pixel circuit PC1. The second gate insulating layer 142 may have a single- or multi-layered structure. The second gate insulating layer 142 may include an inorganic insulating material such as a silicon nitride (SiNx), a silicon oxide (SiOx), or a silicon oxynitride (SiOxNy).

A second gate conductive layer including a first storage electrode 1153 may be positioned on the second gate insulating layer 142. The second gate conductive layer may have a single- or multi-layered structure. The second gate conductive layer may include a metallic material such as molybdenum (Mo), aluminum (Al), copper (Cu), titanium (Ti), or an alloy thereof. The first storage electrode 1153 may overlap the gate electrode 1151 in a plan view to configure a storage capacitor.

A first interlayer insulating layer 160 may be positioned on the second gate conductive layer including the first storage electrode 1153. The first interlayer insulating layer 160 may have a single- or multi-layered structure. The first interlayer insulating layer 160 may include an inorganic insulating material or an organic insulating material.

A first data conductive layer including the source electrode 1173 and the drain electrode 1175 of the first pixel circuit PC1 may be positioned on the first interlayer insulating layer 160. The first data conductive layer may include at least one of aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), copper (Cu), and an alloy thereof.

The first interlayer insulating layer 160 may include an opening overlapping the source electrode 1173 of the first pixel circuit PC1 and the first region 1131 of the semiconductor 1130 in a plan view. The source electrode 1173 of the first pixel circuit PC1 may be electrically connected to the first region 1131 of the semiconductor 1130 through the opening. The first interlayer insulating layer 160 may include an opening overlapping the drain electrode 1175 of the first pixel circuit PC1 and the second region 1133 of the semiconductor 1130 in a plan view. The drain electrode 1175 of the first pixel circuit PC1 may be electrically connected to the second region 1133 of the semiconductor 1130 through the opening.

A first passivation layer 180 may be positioned on the first data conductive layer including the source electrode 1173 and the drain electrode 1175 of the first pixel circuit PC1. The first passivation layer 180 may include an inorganic insulating material such as a silicon nitride (SiNx), a silicon oxide (SiOx), a silicon oxynitride (SiON), or the like and/or an organic insulating material such as a polyimide, an acryl-based polymer, a siloxane-based polymer, or the like.

A second data conductive layer including a connecting electrode 510 of the first pixel circuit PC1 may be positioned on the first passivation layer 180. The second data conductive layer may include at least one of aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), copper (Cu), and an alloy thereof.

The first passivation layer 180 may include an opening overlapping the drain electrode 1175 of the first pixel circuit PC1 in a plan view. The connecting electrode 510 of the first pixel circuit PC1 may be electrically connected to the drain electrode 1175 through the opening.

A second passivation layer 182 may be positioned on the second data conductive layer including the connecting electrode 510 of the first pixel circuit PC1. The second passivation layer 182 may include an organic insulating material including a general purpose polymer such as polymethyl methacrylate or polystyrene, a polymer derivative having at least one of a phenol-based group, an acryl-based polymer, an imide-based polymer, a polyimide, and a siloxane-based polymer.

The first light emitting device ED1 electrically connected to the first pixel circuit PC1 may be positioned on the second passivation layer 182. The first light emitting device ED1 may include a pixel electrode 1191, an emission layer 1370, and a common electrode 270.

The pixel electrode 1191 of the first light emitting device ED1 may be positioned on the second passivation layer 182. The second passivation layer 182 may include an opening 1181 overlapping the pixel electrode 1191 of the first light emitting device ED1 and the connecting electrode 510 of the first pixel circuit PC1 in a plan view. The pixel electrode 1191 of the first light emitting device ED1 may be electrically connected to the connecting electrode 510 of the first pixel circuit PC1 through the opening 1181. Therefore, the pixel electrode 1191 of the first light emitting device ED1 may be electrically connected to the drain electrode 1175 of the first pixel circuit PC1 through the connecting electrode 510.

A partition wall 350 may be positioned on the pixel electrode 1191 of the first light emitting device ED1. A pixel opening 1351 may be formed in the partition wall 350, and the pixel opening 1351 of the partition wall 350 may overlap the pixel electrode 1191 in a plan view.

The emission layer 1370 of the first light emitting device ED1 may be positioned in the pixel opening 1351 of the partition wall 350. The emission layer 1370 may overlap the pixel electrode 1191 in a plan view.

The common electrode 270 may be positioned on the emission layer 1370 and the partition wall 350.

The first light emitting device ED1 may emit light in the region in which the pixel electrode 1191, the emission layer 1370, and the common electrode 270 overlap each other in a plan view. The light emitting region of the first light emitting device ED1 may overlap the first pixel circuit PC1 electrically connected to the light emitting region in a plan view.

Each of the first light emitting devices ED1 may display at least one of a first color, a second color, and a third color. For example, the first light emitting device ED1 may display red (R), green (G), and blue (B).

The light emitting region of the second light emitting device ED2 of the display device according to an embodiment may overlap the second pixel circuit PC2 electrically connected to the second light emitting device ED2 in a plan view. In another embodiment, the light emitting region of the second light emitting device ED2 of the display device may not overlap (or may be spaced apart from) the second pixel circuit PC2 in a plan view. Part of the second light emitting devices ED2 may overlap the second pixel circuit PC2 electrically connected to the second light emitting device ED2 in a plan view. Other part of the second light emitting devices ED2 may overlap the driving circuit DR in a plan view.

The second pixel circuit PC2 may include a semiconductor 2130, a gate electrode 2151, a source electrode 2173, and a drain electrode 2175 positioned in the second display area DA2 of the substrate 110. The driving circuit DR may include a semiconductor 3130, a gate electrode 3151, a source electrode 3173, and a drain electrode 3175 positioned in the second display area DA2 of the substrate 110.

A buffer layer 111 may be positioned on the substrate 110, and the semiconductor 2130 of the second pixel circuit PC2 and the semiconductor 3130 of the driving circuit DR may be positioned on the buffer layer 111. The semiconductor 2130 of the second pixel circuit PC2 and the semiconductor 3130 of the driving circuit DR may be positioned on the semiconductor layer (or positioned on a same layer). For example, the semiconductor 1130 of the first pixel circuit PC1, the semiconductor 2130 of the second pixel circuit PC2, and the semiconductor 3130 of the driving circuit DR may be positioned on a same layer. The semiconductor 2130 of the second pixel circuit PC2 may include a first region 2131, a channel 2132, and a second region 2133.

The first gate insulating layer 141 may be positioned on the semiconductor 2130 of the second pixel circuit PC2 and the semiconductor 3130 of the driving circuit DR. The gate electrode 2151 of the second pixel circuit PC2 and the gate electrode 3151 of the driving circuit DR may be positioned on the first gate insulating layer 141. The gate electrode 2151 of the second pixel circuit PC2 and the gate electrode 3151 of the driving circuit DR may be positioned on the first gate conductive layer (or positioned on a same layer). For example, the gate electrode 1151 of the first pixel circuit PC1, the gate electrode 2151 of the second pixel circuit PC2, and the gate electrode 3151 of the driving circuit DR may be positioned on a same layer. The gate electrode 2151 of the second pixel circuit PC2 may overlap the channel 2132 of the semiconductor 2130 in a plan view.

The second gate insulating layer 142 may be positioned on the gate electrode 2151 of the second pixel circuit PC2 and the gate electrode 3151 of the driving circuit DR. The first storage electrode 2153 of the second pixel circuit PC2 and the first storage electrode 3153 of the driving circuit DR may be positioned on the second gate insulating layer 142 (or positioned on a same layer). For example, the first storage electrode 1153 of the first pixel circuit PC1, the first storage electrode 2153 of the second pixel circuit PC2, and the first storage electrode 3153 of the driving circuit DR may be positioned on a same layer. The first storage electrode 2153 of the second pixel circuit PC2 may overlap the gate electrode 2151 of the second pixel circuit PC2 in a plan view. The first storage electrode 3153 of the driving circuit DR may overlap the gate electrode 3151 of the driving circuit DR in a plan view.

The first interlayer insulating layer 160 may be positioned on the first storage electrode 2153 of the second pixel circuit PC2 and the first storage electrode 3153 of the driving circuit DR. The source electrode 2173 and the drain electrode 2175 of the second pixel circuit PC2 and the source electrode 3173 and the drain electrode 3175 of the driving circuit DR may be positioned on the first interlayer insulating layer 160 (or positioned on a same layer). For example, the source electrode 1173 and the drain electrode 1175 of the first pixel circuit PC1, the source electrode 2173 and the drain electrode 2175 of the second pixel circuit PC2, and the source electrode 3173 and the drain electrode 3175 of the driving circuit DR may be positioned on a same layer. The source electrode 2173 and the drain electrode 2175 of the second pixel circuit PC2 and the source electrode 3173 and the drain electrode 3175 of the driving circuit DR may be positioned on the first data conductive layer.

The first interlayer insulating layer 160 may include an opening overlapping the source electrode 2173 of the second pixel circuit PC2 and the first region 2131 of the semiconductor 2130 in a plan view. The source electrode 2173 of the second pixel circuit PC2 may be electrically connected to the first region 2131 of the semiconductor 2130 through the opening. The first interlayer insulating layer 160 may include an opening overlapping the drain electrode 2175 of the second pixel circuit PC2 and the second region 2133 of the semiconductor 2130 in a plan view. The drain electrode 2175 of the second pixel circuit PC2 may be electrically connected to the second region 2133 of the semiconductor 2130 through the opening. The source electrode 3173 of the driving circuit DR may be electrically connected to a first region of the semiconductor 3130, and the drain electrode 3175 may be electrically connected to a second region of the semiconductor 3130.

The first data conductive layer may further include an initialization voltage line 127. The initialization voltage line 127 may transmit an initialization voltage Vint (e.g., refer to FIG. 5). The initialization voltage Vint (e.g., refer to FIG. 5) may be a constant voltage. For example, the constant voltage (e.g., initialization voltage Vint) may be applied to the initialization voltage line 127.

The first passivation layer 180 may be positioned on the source electrode 2173 and the drain electrode 2175 of the second pixel circuit PC2 and the source electrode 3173 and drain electrode 3175 of the driving circuit DR.

The connecting electrode 520 of the second pixel circuit PC2 may be positioned on the first passivation layer 180. The connecting electrode 520 of the second pixel circuit PC2 may be positioned on the second data conductive layer. The first passivation layer 180 may include an opening overlapping the drain electrode 2175 of the second pixel circuit PC2 in a plan view. The connecting electrode 520 of the second pixel circuit PC2 may be electrically connected to the drain electrode 2175 through the opening.

The second data conductive layer may further include a shield electrode 530. The first passivation layer 180 may include an opening overlapping the initialization voltage line 127 in a plan view. The shield electrode 530 may be electrically connected to the initialization voltage line 127 through the opening. The shield electrode 530 may overlap the driving circuit DR and may cover the driving circuit DR in a plan view. The shield electrode 530 may receive the initialization voltage Vint (e.g., refer to FIG. 5) through the initialization voltage line 127.

The shield electrode 530 may be positioned between the driving circuit DR and the second light emitting device ED2. The second light emitting device ED2 may overlap the driving circuit DR in a plan view and may be influenced (e.g., electrically or electromagnetically influenced) by the voltage applied to the driving circuit DR. However, in the display device according to an embodiment, the shield electrode 530 to which the constant voltage such as the initialization voltage Vint (e.g., refer to FIG. 5) is applied may shield the influence (e.g., electrically or electromagnetically influence) applied to the second light emitting device ED2 by the driving circuit DR. The shield electrode 530 may be electrically connected to the initialization voltage line 127, but is not limited thereto. The shield electrode 530 may be electrically connected to another wire, and a constant voltage which may be different from the initialization voltage Vint (e.g., refer to FIG. 5) may be applied to the shield electrode 530. For example, the shield electrode 530 may be electrically connected to the wire for applying a common voltage ELVSS (e.g., refer to FIG. 5).

A second interlayer insulating layer 162 may be positioned on the connecting electrode 520 of the second pixel circuit PC2. Part of the connecting electrode 520 of the second pixel circuit PC2 may be covered by the second interlayer insulating layer 162. Other part of the connecting electrode 520 of the second pixel circuit PC2 may not be covered by the second interlayer insulating layer 162 but covered by the second passivation layer 182.

An extending wire 600 may be positioned on the second interlayer insulating layer 162. The extending wire 600 may be electrically connected to the connecting electrode 520 of the second pixel circuit PC2, and the connection relationship (e.g., electrical connection between extending wire 600 and connecting electrode 520) may be provided below with reference to FIG. 4. The extending wire 600 and the second interlayer insulating layer 162 may be simultaneously patterned by using a same mask. Therefore, the extending wire 600 and the second interlayer insulating layer 162 may have substantially a same planar shape. The extending wire 600 may be positioned in the second display area DA2 and may not be positioned in the first display area DA1. The second interlayer insulating layer 162 may be positioned in the second display area DA2 and may not be positioned in the first display area DA1. Therefore, the second interlayer insulating layer 162 may overlap at least part of the second pixel circuit PC2 and the second light emitting device ED2 in a plan view, and may not overlap (or may be spaced apart from) the first pixel circuit PC1 and the first light emitting device ED1 in a plan view. The extending wire 600 and the second interlayer insulating layer 162 may be simultaneously patterned using the same mask, and the number of masks used in a process for manufacturing the display device according to an embodiment may be reduced. Therefore, process cost and time may be reduced. The extending wire 600 may overlap a part of an edge of the connecting electrode 520 of the second pixel circuit PC2 in a plan view. The second interlayer insulating layer 162 may be positioned between the extending wire 600 and the connecting electrode 520 of the second pixel circuit PC2, and the extending wire 600 may not be directly connected to (or may be spaced apart from) the connecting electrode 520 of the second pixel circuit PC2. For example, the extending wire 600 may not be directly connected to the connecting electrode 520, but electrically connected to the connecting electrode 520 of the second pixel circuit PC2 through a bridge electrode 195. The extending wire 600 may overlap the shield electrode 530 in a plan view. The second interlayer insulating layer 162 may be positioned between the extending wire 600 and the shield electrode 530. The extending wire 600 and the shield electrode 530 may be electrically insulated by the second interlayer insulating layer 162.

The second passivation layer 182 may be positioned on the connecting electrode 520 of the second pixel circuit PC2 and the extending wire 600. The second passivation layer 182 may include an overlapping portion of the connecting electrode 520 of the second pixel circuit PC2 and the extending wire 600 in a plan view, and an opening 2183 overlapping peripheral portions thereof in a plan view. The bridge electrode 195 may be positioned on the second passivation layer 182. The bridge electrode 195 and the pixel electrode 1191 of the first light emitting device ED1 may be positioned on a same layer. The bridge electrode 195 may be positioned in the opening 2183, and may be electrically connected to the connecting electrode 520 of the second pixel circuit PC2 and the extending wire 600 in the opening 2183. Therefore, the extending wire 600 and the connecting electrode 520 of the second pixel circuit PC2 may be electrically connected by the bridge electrode 195.

The second light emitting devices ED2 electrically connected to the second pixel circuit PC2 may be positioned on the second passivation layer 182. For example, the second pixel circuit PC2 may be electrically connected to two of the second light emitting devices ED2. The number of the second light emitting devices ED2 electrically connected to the second pixel circuit PC2 is not limited thereto, and the second pixel circuit PC2 may be electrically connected to at least three second light emitting devices ED2. Each of the second light emitting devices ED2 may include a pixel electrode 2191, an emission layer 2370, and the common electrode 270.

The pixel electrode 2191 of each of the second light emitting device ED2 may be positioned on the second passivation layer 182. For example, the pixel electrode 2191 of the second light emitting device ED2, the pixel electrode 1191 of the first light emitting device ED1, and the bridge electrode 195 may be positioned on a same layer (e.g., second passivation layer 182). The second passivation layer 182 may include an opening 2181 overlapping the pixel electrode 2191 of the second light emitting device ED2 and the extending wire 600 in a plan view. The pixel electrode 2191 of each of the second light emitting devices ED2 may be electrically connected to the extending wire 600 through the opening 2181. The extending wire 600 may be electrically connected to the second pixel circuit PC2 through the bridge electrode 195. Therefore, the extending wire 600 may connect (e.g., electrically connect) between the second pixel circuit PC2 and the second light emitting devices ED2. At least part of the second light emitting devices ED2 may not overlap (or may be spaced apart from) the second pixel circuit PC2 electrically connected to the second light emitting device ED2 in a plan view, and may be distant from the second pixel circuit PC2 in the plan view. The extending wire 600 may connect (or electrically connect) the second light emitting devices ED2 and the second pixel circuit PC2 spaced apart from each other.

The second pixel circuit PC2 and the second light emitting device ED2 may be electrically connected to each other by the extending wire 600, but are not limited thereto. In another embodiments, the extending wire 600 may be omitted, and the pixel electrode 2191 of the second light emitting device ED2 may extend to reach the second pixel circuit PC2. The pixel electrodes 2191 of the second light emitting devices ED2 may extend in a direction, and the pixel electrode 2191 may detour to avoid collision with adjacent pixels and may be electrically connected to the second pixel circuit PC2. However, in case that the extending wire 600 is omitted, the process for extending the pixel electrode 2191 may become complicated, and a short-circuit may be generated. In the embodiment of the disclosure, the display device may include the extending wire 600, and the extending wire 600 may be disposed on a different layer from that of the pixel electrode 2191 of the second light emitting device ED2, thereby simplifying the wire design of the display device and preventing the short-circuit.

A partition wall 350 may be positioned on the pixel electrode 2191 of the second light emitting device ED2. A pixel opening 2351 may be formed in the partition wall 350, and the pixel opening 2351 of the partition wall 350 may overlap the pixel electrode 2191 in a plan view.

An emission layer 2370 of the second light emitting device ED2 may be positioned in the pixel opening 2351 of the partition wall 350. The emission layer 2370 may overlap the pixel electrode 2191 in a plan view.

A common electrode 270 may be positioned on the emission layer 2370 and the partition wall 350. The common electrode 270 of the second light emitting device ED2 and the common electrode 270 of the first light emitting device ED1 may be integrally formed, and may be positioned in the most region of the substrate 110.

The second light emitting device ED2 may emit light in the region in which the pixel electrode 2191, the emission layer 2370, and the common electrode 270 overlap each other in a plan view. The light emitting region of the second light emitting device ED2 may overlap the second pixel circuit PC2 electrically connected to the light emitting region in a plan view. In another embodiment, the light emitting region of the second light emitting device ED2 may not overlap (or may be spaced apart from) the second pixel circuit PC2 in a plan view

Regarding the display device according to an embodiment, the second light emitting device ED2 may be positioned in the region including the second pixel circuit PC2 and the region in which the driving circuit (DR) is disposed. Thus, the region for displaying the screen may be increased. Therefore, a pixel density of the second display area DA2 may be smaller than a pixel density of the first display area DA1. The size of the second light emitting device ED2 may be increased to compensate for the decreased pixel density in the second display area DA2 and increase luminance of the second light emitting device ED2. The sizes of the elements such as the storage capacitor included in the second pixel circuit PC2 may be increased, and an amount of current applied to the second light emitting device ED2 may be increased. For example, an area of the second pixel circuit PC2 may increase. For example, the area of the second pixel circuit PC2 may be twice the area of the first pixel circuit PCL. The area of the second light emitting device ED2 may be twice the area of the first light emitting device ED1. This is, however, an example, and the areas of the second pixel circuit PC2 and the second light emitting device ED2 may be set in various ways.

The second light emitting devices ED2 may be electrically connected to the second pixel circuit PC2, and the resolution of the second display area DA2 may be increased. For example, the resolution of the second display area DA2 may be similar to the resolution of the first display area DA1.

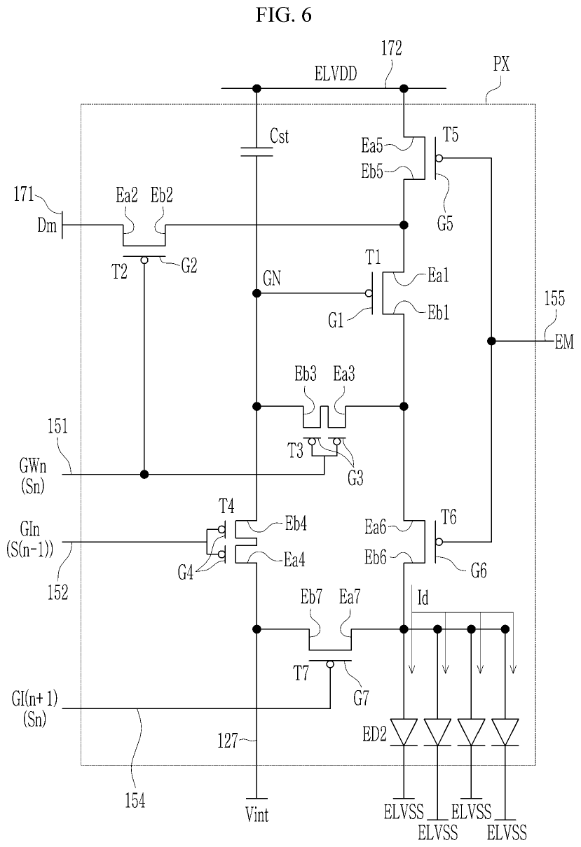

One transistor of each of the pixel circuits PC1 and PC2 has been described. However, each of the pixel circuits PC1 and PC2 may include multiple transistors. An example of a pixel of a display device according to an embodiment is provided below with reference to FIGS. 5 and 6.

FIGS. 5 and 6 show schematic circuit diagrams of pixels of display devices according to embodiments. FIG. 5 shows a pixel positioned in the first display area DA1 of the display device according to an embodiment, and FIG. 6 shows a pixel positioned in the second display area DA2 of the display device according to an embodiment.

As shown in FIG. 5, the display device according to an embodiment may include multiple pixels PXs for displaying images and signal lines 127, 151, 152, 153, 154, 171, and 172. A pixel PX positioned in the first display area DA1 of the display device according to an embodiment may include transistors T1, T2, T3, T4, T5, T6, and T7 electrically connected to the signal lines 127, 151, 152, 153, 154, 171, and 172, a capacitor Cst, and a first light emitting device ED1.

The signal lines 127, 151, 152, 154, 155, 171, and 172 may include the initialization voltage line 127, scan lines 151, 152, and 154, a 155, the data line 171, and a driving voltage line 172.

The initialization voltage line 127 may transmit the initialization voltage Vint. The scan lines 151, 152, and 154 may transmit scan signals GWn, GIn, and GI(n+1). The scan signals GWn, GIn, and GI(n+1) may transmit a gate-on voltage and a gate-off voltage for turning on/off the transistors T2, T3, T4, and T7 included by the pixel PX.

The scan lines 151, 152, and 154 electrically connected to the pixel PX may include a first scan line 151 for transmitting a scan signal GWn, a second scan line 152 for transmitting the scan signal GIn with a gate-on voltage at a different timing from the first scan line 151, and a third scan line 154 for transmitting the scan signal GI(n+1). In the embodiment, the second scan line 152 may transmit a gate-on voltage at a prior timing to the first scan line 151. For example, in case that the scan signal GWn is the n-th scan signal Sn (n is a natural number that is equal to or greater than 1) among the scan signals applied for a frame, the scan signal GIn may be a previous-stage scan signal such as the (n−1)-th scan signal (S(n−1)), or the like, and the scan signal GI(n+1) may be n-th scan signal Sn. However, the embodiment is not limited thereto, and the scan signal GI(n+1) may be a scan signal that is different from the n-th scan signal Sn.

The light-emitting control line 155 may transmit a control signal. For example, the light-emitting control line 155 may transmit a light-emitting control signal EM for controlling light emission of the first light emitting device ED1 of the pixel PX. The control signal transmitted by the light-emitting control line 155 may transmit the gate-on voltage and the gate-off voltage, and may have a waveform that is different from the scan signal transmitted by the scan lines 151, 152, and 154.

The data line 171 may transmit a data signal Dm, and the driving voltage line 172 may transmit a driving voltage ELVDD. The data signal Dm may have different voltage levels depending on the image signal input to the display device, and the driving voltage ELVDD may substantially have a constant level.

Although not shown, the display device may further include a driving circuit for transmitting signal to the signal lines 127, 151, 152, 153, 154, 171, and 172.

The transistors T1, T2, T3, T4, T5, T6, and T7 included in the pixel PX may include a first transistor T1, a second transistor T2, a third transistor T3, a fourth transistor T4, a fifth transistor T5, a sixth transistor T6, and a seventh transistor T7.

The first scan line 151 may transmit the scan signal GWn to the second transistor T2 and third transistor T3. The second scan line 152 may transmit the scan signal GIn to the fourth transistor T4. The third scan line 154 may transmit the scan signal GI(n+1) to the seventh transistor T7. The light-emitting control line 155 may transmit the light-emitting control signal EM to the fifth transistor T5 and the sixth transistor T6.

A gate electrode G1 of the first transistor T1 may be electrically connected to an end of the capacitor Cst through a driving gate node GN. A first electrode Ea1 of the first transistor T1 may pass through the fifth transistor T5 and may be electrically connected to the driving voltage line 172. A second electrode Eb1 of the first transistor T1 may pass through the sixth transistor T6 and may be electrically connected to an anode of the first light emitting device ED1. The first transistor T1 may receive the data signal Dm transmitted by the data line 171 and may supply a driving current Id to the first light emitting device ED1 according to a switching operation of the second transistor T2.

A gate electrode G2 of the second transistor T2 may be electrically connected to the first scan line 151. A first electrode Ea2 of the second transistor T2 may be electrically connected to the data line 171. A second electrode Eb2 of the second transistor T2 may be electrically connected to the first electrode Ea1 of the first transistor T1 and may be electrically connected to the driving voltage line 172 through the fifth transistor T5. The second transistor T2 may be turned on by the scan signal GWn received through the first scan line 151. The second transistor T2 may transmit the data signal Dm transmitted from the data line 171 to the first electrode Ea1 of the first transistor T1.

A gate electrode G3 of the third transistor T3 may be electrically connected to the first scan line 151. A first electrode Ea3 of the third transistor T3 may be electrically connected to the second electrode Eb1 of the first transistor T1 and may be electrically connected to the anode of the first light emitting device ED1 through the sixth transistor T6. A second electrode Eb3 of the third transistor T3 may be electrically connected to a second electrode Eb4 of the fourth transistor T4. A first end of the capacitor Cst, and the gate electrode G1 of the first transistor T1. The third transistor T3 may be turned on by the scan signal GWn received through the first scan line 151 and may electrically connect the gate electrode G1 of the first transistor T1 and the second electrode Eb1. Thus, the first transistor T1 may be diode-connected.

A gate electrode G4 of the fourth transistor T4 may be electrically connected to the second scan line 152. A first electrode Ea4 of the fourth transistor T4 may be electrically connected to an initialization voltage Vint terminal. The second electrode Eb4 of the fourth transistor T4 may pass through the second electrode Eb3 of the third transistor T3 and may be electrically connected to the first end of the capacitor Cst and the gate electrode G1 of the first transistor T1. The fourth transistor T4 may be turned on by the scan signal GIn received through the second scan line 152 and may transmit the initialization voltage Vint to the gate electrode G1 of the first transistor T1 to initialize the voltage at the gate electrode G1 of the first transistor T1. Thus, an initialization operation may be performed.

A gate electrode G5 of the fifth transistor T5 may be electrically connected to the light-emitting control line 155. A first electrode Ea5 of the fifth transistor T5 may be electrically connected to the driving voltage line 172. A second electrode Eb5 of the fifth transistor T5 may be electrically connected to the first electrode Ea1 of the first transistor T1 and the second electrode Eb2 of the second transistor T2.

A gate electrode G6 of the sixth transistor T6 may be electrically connected to the light-emitting control line 155. A first electrode Ea6 of the sixth transistor T6 may be electrically connected to the second electrode Eb1 of the first transistor T1 and a first electrode Ea3 of the third transistor T3. A second electrode Eb6 of the sixth transistor T6 may be electrically connected to the anode of the first light emitting device ED1. The fifth transistor T5 and the sixth transistor T6 may be simultaneously turned on by the light-emitting control signal EM received through the light-emitting control line 155. The driving voltage ELVDD may be compensated through the diode-connected first transistor T1 and may be transmitted to the first light emitting device ED1.

A gate electrode G7 of the seventh transistor T7 may be electrically connected to the third scan line 154. A first electrode Ea7 of the seventh transistor T7 may be electrically connected to the second electrode Eb6 of the sixth transistor T6 and the anode of the first light emitting device ED1. A second electrode Eb7 of the seventh transistor T7 may be electrically connected to the initialization voltage Vint terminal and the first electrode Ea4 of the fourth transistor T4.

The transistors T1, T2, T3, T4, T5, T6, and T7 may be p-type channel transistors such as PMOS. However, the transistors T1, T2, T3, T4, T5, T6, and T7 are not limited thereto, and at least one of the transistors T1, T2, T3, T4, T5, T6, and T7 may be an n-type channel transistor.

The first end of the capacitor Cst may be electrically connected to the gate electrode G1 of the first transistor T1. A second end of the capacitor Cst may be electrically connected to the driving voltage line 172. A cathode of the first light emitting device ED1 may be electrically connected to a common voltage ELVSS terminal for transmitting the common voltage ELVSS and may receive the common voltage ELVSS.

As shown in FIG. 6, the pixel PX positioned in the second display area DA2 of the display device according to an embodiment may include transistors T1, T2, T3, T4, T5, T6, and T7 electrically connected to the signal lines 127, 151, 152, 153, 154, 171, and 172, a capacitor Cst, and the second light emitting device ED2.

Each of the pixels PX positioned in the first display area DA1 may include the first light emitting device ED1, and each of the pixels PX positioned in the second display area DA2 may include multiple second light emitting devices ED2. The second light emitting devices ED2 positioned in each of the pixels PX of the second display area DA2 may receive a divided driving current Id. The second light emitting devices ED2 may be electrically connected to each other, and the second light emitting devices ED2 may receive a same signal and may have a same luminance. FIG. 6 illustrates a structure in which the pixel PX includes four second light emitting devices ED2 electrically connected to each other, but the structure may be not limited thereto. One pixel PX of the second display area DA2 may include two or three second light emitting devices ED2 electrically connected to each other, and the pixel PX of the second display area DA2 may include at least five second light emitting devices ED2.

The pixel PX positioned in the first display area DA1 and the pixel PX positioned in the second display area DA2 may have different number of light emitting devices and have a same transistor connecting structure, but are not limited thereto. For example, the pixel PX positioned in the first display area DA1 and the pixel PX positioned in the second display area DA2 may have different transistor connecting structures. Further, the pixel circuit structures shown in FIGS. 5 and 6 are an example, and the number of transistors and capacitors included in the pixel PX of the display device according to an embodiment and connection relationships thereof may be modifiable in many ways.

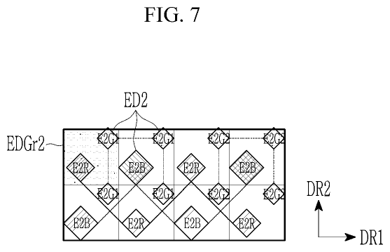

Each of the first pixel circuits PC1 in the display device according to an embodiment may be electrically connected to a first light emitting device ED1, and the respective second pixel circuits PC2 may be electrically connected to second light emitting devices ED2. The second light emitting devices ED2 electrically connected to the second pixel circuits PC2 may be disposed in many ways, and various types of arrangements of the second light emitting devices ED2 are provided below with reference to FIGS. 7 to 9.

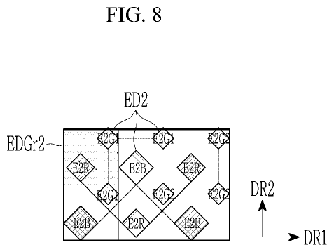

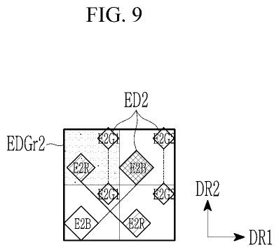

FIGS. 7 to 9 show schematic views of arrangements of second light emitting devices of display devices according to embodiments. FIG. 7 shows a second pixel circuit PC2 electrically connected to four second light emitting devices ED2. FIG. 8 shows a second pixel circuit PC2 electrically connected to three second light emitting devices ED2. FIG. 9 shows a second pixel circuit PC2 electrically connected to two second light emitting devices ED2.

As shown in FIG. 7, the second light emitting devices ED2 may be disposed (or arranged) in a first direction DR1 and a second direction DR2, and disposed in the second display area DA2 of the substrate of the display device according to an embodiment.

The second light emitting device ED2 may include a first sub-light emitting device E2R, a second sub-light emitting device E2B, a third sub-light emitting device E2G1, and a fourth sub-light emitting device E2G2. The first sub-light emitting device E2R, the second sub-light emitting device E2B, the third sub-light emitting device E2G1, and the fourth sub-light emitting device E2G2 may respectively emit light of colors. For example, the first sub-light emitting device E2R may emit red light, and the second sub-light emitting device E2B may emit blue light. The third sub-light emitting device E2G1 and the fourth sub-light emitting device E2G2 may emit green light. In a first row, the first sub-light emitting device E2R, the third sub-light emitting device E2G1, the second sub-light emitting device E2B, and the third sub-light emitting device E2G1 may be sequentially disposed (or arranged) in the first direction DR1. In a second row, the second sub-light emitting device E2B, the fourth sub-light emitting device E2G2, the first sub-light emitting device E2R, and the fourth sub-light emitting device E2G2 may be sequentially disposed (or arranged) in the first direction DR1. The first sub-light emitting device E2R and the second sub-light emitting device E2B may be near (or adjacent to) each other in the second direction DR2. The third sub-light emitting device E2G1 and the fourth sub-light emitting device E2G2 may be near (or adjacent to) each other in the second direction DR2.

The sixteen second light emitting devices ED2 that are adjacent to each other in the first direction DR1 and the second direction DR2 may configure a second light emitting device group EDGr2. The sixteen second light emitting devices ED2 may be substantially arranged in a 2×8 matrix form in each of the second light emitting device groups EDGr2. The second light emitting device groups EDGr2 may include four first sub-light emitting devices E2R, four second sub-light emitting devices E2B, four third sub-light emitting devices E2G1, and four fourth sub-light emitting devices E2G2.

The first sub-light emitting devices E2R positioned in the second light emitting device group EDGr2 may be electrically connected to each other. For example, the four first sub-light emitting devices E2R positioned in the second light emitting device group EDGr2 may be electrically connected to a same second pixel circuit and receive a same signal. Therefore, the first sub-light emitting devices E2R electrically connected to each other may have a same luminance.

The second sub-light emitting devices E2B positioned in the second light emitting device group EDGr2 may be electrically connected to each other. For example, the four second sub-light emitting devices E2B positioned in the second light emitting device group EDGr2 may be electrically connected to a same second pixel circuit and receive a same signal. Therefore, the second sub-light emitting devices E2R electrically connected to each other may have a same luminance.

The third sub-light emitting devices E2G1 positioned in the second light emitting device group EDGr2 may be electrically connected to each other. For example, the four third sub-light emitting devices E2G1 positioned in the second light emitting device group EDGr2 may be electrically connected to a same second pixel circuit and receive a same signal. Thus, the third sub-light emitting devices E2G1 electrically connected to each other may have a same luminance.

The fourth sub-light emitting devices E2G2 positioned in the second light emitting device group EDGr2 may be electrically connected to each other. For example, the four fourth sub-light emitting devices E2G2 positioned in the second light emitting device group EDGr2 may be electrically connected to a same second pixel circuit and receive a same signal. Therefore, the fourth sub-light emitting devices E2G2 electrically connected to each other may have a same luminance.

As shown in FIG. 8, twelve second light emitting devices ED2 that are near (or adjacent to) each other in the first direction DR1 and the second direction DR2 may configure a second light emitting device group EDGr2. The twelve second light emitting devices ED2 may be substantially arranged in a 2×6 matrix form in each of the second light emitting device groups EDGr2. The second light emitting device group EDGr2 may include three first sub-light emitting devices E2R, three second sub-light emitting devices E2B, three third sub-light emitting devices E2G1, and three fourth sub-light emitting devices E2G2.

The three first sub-light emitting devices E2R positioned in the second light emitting device group EDGr2 may be electrically connected to each other and may have a same luminance. The three second sub-light emitting devices E2B positioned in the second light emitting device group EDGr2 may be electrically connected to each other and may have a same luminance. The three third sub-light emitting devices E2G1 positioned in the second light emitting device group EDGr2 may be electrically connected to each other and may have a same luminance. The three fourth sub-light emitting devices E2G2 positioned in the second light emitting device group EDGr2 may be electrically connected to each other and may have a same luminance.

As shown in FIG. 9, eight second light emitting devices ED2 that are near (or adjacent to) each other in the first direction DR1 and the second direction DR2 may configure a second light emitting device group EDGr2. The eight second light emitting devices ED2 may be substantially arranged in a 2×4 matrix form in each of the second light emitting device group EDGr2. The second light emitting device group EDGr2 may include two first sub-light emitting devices E2R, two second sub-light emitting devices E2B, two third sub-light emitting devices E2G1, and two fourth sub-light emitting devices E2G2.

The two first sub-light emitting devices E2R positioned in the second light emitting device group EDGr2 may be electrically connected to each other and may have a same luminance. The two second sub-light emitting devices E2B positioned in the second light emitting device group EDGr2 may be electrically connected to each other and may have a same luminance. The two third sub-light emitting devices E2G1 positioned in the second light emitting device group EDGr2 may be electrically connected to each other and may have a same luminance. The two fourth sub-light emitting devices E2G2 positioned in the second light emitting device group EDGr2 may be electrically connected to each other and may have a same luminance.

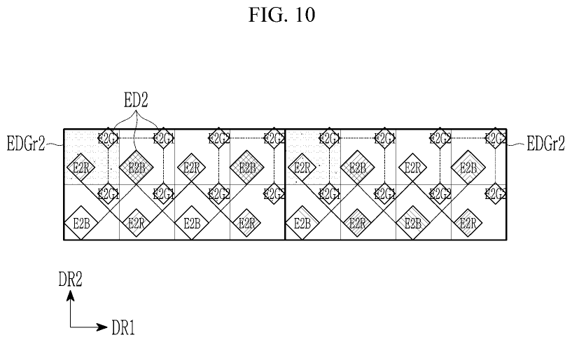

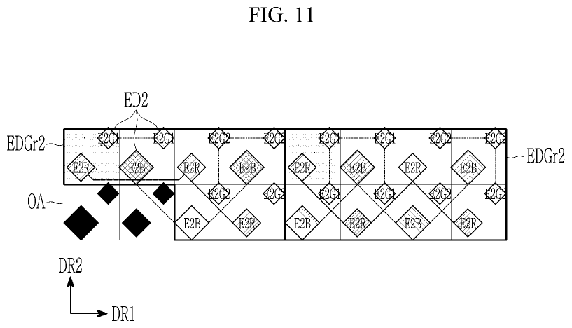

The arrangements of the second light emitting device ED2 shown in FIGS. 7 to 9 are some of the various arrangements of the disclosure, and the disclosure is not limited thereto. The disclosure may be modifiable in many ways. The arrangement of the second light emitting devices ED2 positioned in a straight portion STR at an edge of the display area DA of the display device according to an embodiment may be different from the arrangement of the second light emitting devices ED2 positioned on a round portion RND, which is provided below with reference to FIGS. 10 and 11.

FIGS. 10 and 11 show schematic views of arrangements of second light emitting devices of display devices according to embodiments. FIG. 10 shows a straight portion STR of an edge of a display area DA of a display device according to an embodiment and a peripheral area adjacent to the straight portion, and FIG. 11 shows a round portion RND of an edge of a display area DA of a display device according to an embodiment and a peripheral area adjacent to the round portion. FIGS. 10 and 11 show two second light emitting device groups EDGr2 disposed adjacent to each other, and a left end of the second light emitting device group, EDGr2 which is positioned on the left, is positioned on the edge of the display area DA.

The number of the second light emitting devices ED2 configuring the second light emitting device group EDGr2 positioned on the round portion RND of the edge of the display area DA of the display device according to an embodiment may be different from the number of the second light emitting device ED2 configuring the second light emitting device group EDGr2 positioned in the straight portion STR. The number of the second light emitting devices ED2 configuring the second light emitting device group EDGr2 positioned on the round portion RND may be smaller than the number of the second light emitting devices ED2 configuring the second light emitting device group EDGr2 positioned in the straight portion STR.

As shown in FIG. 10, the number of second light emitting devices ED2 configuring the second light emitting device group EDGr2 positioned in the straight portion STR may be sixteen. The second light emitting device group EDGr2 positioned in the straight portion STR may include four first sub-light emitting devices E2R, four second sub-light emitting devices E2B, four third sub-light emitting devices E2G1, and four fourth sub-light emitting devices E2G2.

As shown in FIG. 11, the number of second light emitting devices ED2 configuring the second light emitting device group EDGr2 positioned on the round portion RND may be twelve. The second light emitting device group EDGr2 positioned on the round portion RND may include three first sub-light emitting devices E2R, three second sub-light emitting devices E2B, two third sub-light emitting devices E2G1, and four fourth sub-light emitting devices E2G2.

The second light emitting device group EDGr2 positioned on the round portion RND may have the arrangement in which at least one second light emitting device ED2 positioned at the edge may be turned off with reference to the second light emitting device group EDGr2 positioned in the straight portion STR. For example, regarding the second light emitting device group EDGr2 positioned on the round portion RND, a first sub-light emitting device E2R, a second sub-light emitting device E2B, and two third sub-light emitting devices E2G1 positioned at the bottom left may be turned off with reference to the second light emitting device group EDGr2 positioned in the straight portion STR. For example, regarding the second light emitting device group EDGr2 positioned on the round portion RND, the second light emitting devices ED2 positioned in the first to fourth columns of the first row among the sixteen second light emitting devices ED2 may be turned off with reference to the second light emitting device group EDGr2 positioned in the straight portion STR. However, the number and the position of the second light emitting devices ED2 that are turned off among the second light emitting device group EDGr2 positioned on the round portion RND may be variable in many ways.

Regarding the display device according to an embodiment, the number of the second light emitting devices ED2 positioned in the second row may be reduced to realize (or form) the round portion RND of the edge of the display area DA. In another embodiment, the number of the second light emitting device group EDGr2 position in the second row may be reduced to realize (or form) the round portion RND of the display device. In a reference example, the round portion RND may have a staircase shape, and may not be realized as a curved line (or soft (or smooth) edge). In the embodiment of the disclosure, some of the second light emitting devices ED2 configuring the second light emitting device group EDGr2 positioned on the round portion RND may be turned off to realize (or form) a soft (or smooth) curved line of the round portion RND.

A pixel electrode and an emission layer may not be positioned in an off area OA in which some of the second light emitting device ED2 are turned off among the second light emitting device group EDGr2, and the round portion RND may be positioned in the off area OA. The pixel electrode may be positioned in the off area OA, but the emission layer may not be positioned in the off area OA. The pixel opening may not be formed in the off area OA.

The second light emitting device group EDGr2 positioned further inside than the second light emitting device group EDGr2 positioned on the round portion RND may have the same arrangement as the second light emitting device group EDGr2 positioned in the straight portion STR. Therefore, the number of the second light emitting devices ED2 configuring the second light emitting device group EDGr2 positioned on the round portion RND may be smaller than the number of the second light emitting devices ED2 configuring the second light emitting device group EDGr2 positioned further inside than the second light emitting device group EDGr2 positioned on the round portion RND.

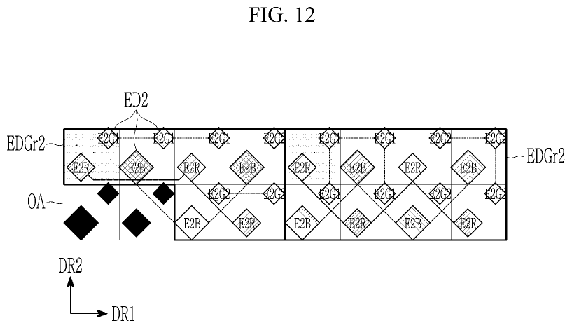

The arrangement of the second light emitting devices ED2 positioned on the round portion RND may be variable in many ways, and a modified example is provided below with reference to FIG. 12.

FIG. 12 shows a schematic diagram of an arrangement of a second light emitting device of a display device according to an embodiment. FIG. 12 illustrates a round portion RND of an edge of a display area DA of a display device according to an embodiment and a peripheral area adjacent to the round portion.

As shown in FIG. 12, the number of second light emitting devices ED2 configuring the second light emitting device group EDGr2 positioned on the round portion RND may be twelve. The second light emitting device group EDGr2 positioned on the round portion RND may include three first sub-light emitting devices E2R, three second sub-light emitting devices E2B, three third sub-light emitting devices E2G1, and three fourth sub-light emitting devices E2G2.

The second light emitting device group EDGr2 positioned on the round portion RND may have an arrangement in which at least one second light emitting device ED2 positioned at the edge is turned off with reference to the second light emitting device group EDGr2 positioned in the straight portion STR. For example, regarding the second light emitting device group EDGr2 positioned on the round portion RND, a first sub-light emitting device E2R, a second sub-light emitting device E2B, a third sub-light emitting device E2G1, and a fourth sub-light emitting device E2G2 positioned at the bottom left may be turned off with reference to the second light emitting device group EDGr2 positioned in the straight portion STR. However, the number and the position of the second light emitting devices ED2 turned off in the second light emitting device group EDGr2 positioned on the round portion RND are not limited thereto, and may be changeable in many ways.

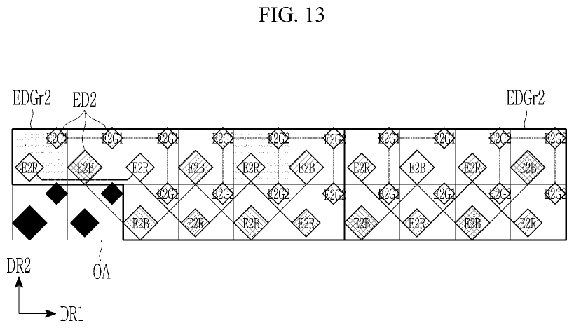

The number of the second light emitting devices ED2 configuring the second light emitting device group EDGr2 positioned on the round portion RND may be greater than the number of the second light emitting devices ED2 configuring the second light emitting device group EDGr2 positioned in the straight portion STR, which is provided below with reference to FIG. 13.

FIG. 13 shows a schematic diagram of an arrangement of a second light emitting device of a display device according to an embodiment. FIG. 13 illustrates a round portion RND of an edge of a display area DA of a display device according to an embodiment and a peripheral area adjacent to the round portion. FIG. 13 illustrates two second light emitting device groups EDGr2 that are near (or adjacent to) each other, and the left end of the second light emitting device group EDGr2 positioned on the left is positioned at the edge of the display area DA.

As shown in FIG. 13, the number of second light emitting devices ED2 configuring the second light emitting device group EDGr2 positioned on the round portion RND may be twenty. The second light emitting device group EDGr2 positioned on the round portion RND may include five first sub-light emitting devices E2R, five second sub-light emitting devices E2B, four third sub-light emitting devices E2G1, and six fourth sub-light emitting devices E2G2.

The second light emitting device group EDGr2 positioned on the round portion RND may have an arrangement in which at least one second light emitting device ED2 position at a first-side edge is turned off and at least one second light emitting device ED2 is added at a second-side edge with reference to the second light emitting device group EDGr2 positioned in the straight portion STR. For example, regarding the second light emitting device group EDGr2 positioned on the round portion RND, four second light emitting devices ED2 positioned at the bottom left may be turned off and eight second light emitting devices ED2 positioned on the right may be added with reference to the second light emitting device group EDGr2 positioned in the straight portion STR. However, the number and the position of the second light emitting devices ED2 turned off in the second light emitting device group EDGr2 positioned on the round portion RND, and the number and the position of the added second light emitting device ED2 are not limited thereto, and may be changeable in many ways.

In the above-described embodiment, the number of the second light emitting devices ED2 configuring the second light emitting device group EDGr2 positioned on the round portion RND may be reduced to realize (or form) the round portion RND of the edge of the display area DA. However, the number of the second light emitting devices ED2 electrically connected to a second pixel circuit may be relatively smaller than the number of the second light emitting devices ED2 in the peripheral area thereto. Thus, the luminance may become relatively high. In the embodiment, the number of the second light emitting devices ED2 configuring the second light emitting device group EDGr2 positioned on the round portion RND may be increased, and the round portion RND of the edge of the display area DA may have a soft (or smooth) curved line. As the number of the second light emitting devices ED2 electrically connected to the second pixel circuit is relatively large, the luminance may become relatively low. Therefore, the round portion RND may be seen as a softer (or smoother) curved line.

The second light emitting device group EDGr2 positioned further inside than the second light emitting device group EDGr2 positioned on the round portion RND may have the same arrangement as the second light emitting device group EDGr2 positioned in the straight portion STR. Thus, the number of the second light emitting device ED2 configuring the second light emitting device group EDGr2 positioned on the round portion RND may be greater than the number of the second light emitting devices ED2 configuring the second light emitting device group EDGr2 positioned further inside than the second light emitting device group EDGr2 positioned on the round portion RND.

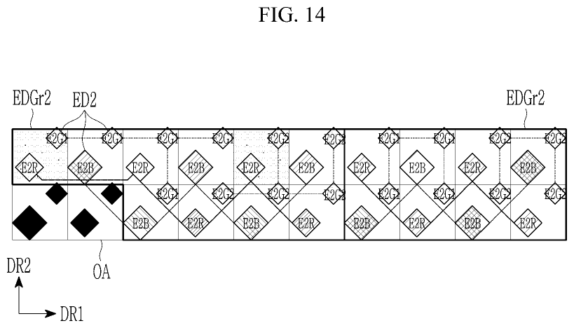

The arrangement of the second light emitting devices ED2 positioned on the round portion RND may be modifiable in many ways, and a modified example is provided below with reference to FIG. 14.

FIG. 14 shows a schematic diagram of an arrangement of a second light emitting device of a display device according to an embodiment. FIG. 14 illustrates a round portion RND of an edge of a display area DA of a display device according to an embodiment and a peripheral area adjacent to the round portion.

As shown in FIG. 14, the number of second light emitting devices ED2 configuring the second light emitting device group EDGr2 positioned on the round portion RND may be twenty. The second light emitting device group EDGr2 positioned on the round portion RND may include five first sub-light emitting devices E2R, five second sub-light emitting devices E2B, five third sub-light emitting devices E2G1, and five fourth sub-light emitting devices E2G2.

The second light emitting device group EDGr2 positioned on the round portion RND may have an arrangement in which at least one second light emitting device ED2 positioned at first-side edge is turned off and at least one second light emitting device ED2 is added at a second-side edge with reference to the second light emitting device group EDGr2 positioned in the straight portion STR. However, the number and the position of the second light emitting devices ED2 turned off in the second light emitting device group EDGr2 positioned on the round portion RND, and the number and the position of the added second light emitting devices ED2 are not limited thereto, and may be changeable in many ways.

While this disclosure has been described in connection with what is presently considered to be embodiments, it is to be understood that the disclosure is not limited to the disclosed embodiments, but, on the contrary, is intended to cover various modifications and equivalent arrangements included within the spirit and scope of the appended claims.

What is claimed is:

1. A display device comprising:
a display area including:
a first display area; and
a second display area;
a first pixel circuit disposed in the first display area;
a first light emitting element electrically connected to the first pixel circuit;
a second pixel circuit disposed in the second display area;
second light emitting elements electrically connected to the second pixel circuit; and
a driving circuit electrically connected to the first pixel circuit and the second pixel circuit and overlapping the second light emitting elements in a plan view, wherein
an edge of the display area includes a straight portion and a round portion,
the second light emitting elements that are near each other in a first direction and a second direction that is perpendicular to the first direction configure a light emitting element group, and
a number of the second light emitting elements configuring the light emitting element group disposed on the round portion is different from a number of the second light emitting elements configuring the light emitting element group disposed on the straight portion.

2. The display device of claim 1, wherein the second light emitting elements includes:
a first sub-light emitting element that emits a first color;
a second sub-light emitting element that emits a second color; and
a third sub-light emitting element and a fourth sub-light emitting element that emit a third color.

3. The display device of claim 2, wherein
the first color is red,
the second color is blue, and
the third color is green.

4. The display device of claim 2, wherein the light emitting element group includes:
first sub-light emitting elements;
second sub-light emitting elements;
third sub-light emitting elements; and
fourth sub-light emitting elements.

5. The display device of claim 4, wherein
the first sub-light emitting elements disposed in the light emitting element group are electrically connected to each other,
the second sub-light emitting elements disposed in the light emitting element group are electrically connected to each other,
the third sub-light emitting elements disposed in the light emitting element group are electrically connected to each other, and
the fourth sub-light emitting elements disposed in the light emitting element group are electrically connected to each other.

6. The display device of claim 5, wherein the number of the second light emitting elements configuring the light emitting element group disposed on the round portion is smaller than the number of the second light emitting elements configuring the light emitting element group disposed on the straight portion.

7. The display device of claim 6, wherein
the number of the second light emitting elements configuring the light emitting element group disposed on the straight portion is sixteen, and
the number of the second light emitting elements configuring the light emitting element group disposed on the round portion is twelve.

8. The display device of claim 7, wherein the light emitting element group disposed on the straight portion includes:
four first sub-light emitting elements;
four second sub-light emitting elements;
four third sub-light emitting elements; and
four fourth sub-light emitting elements.

9. The display device of claim 8, wherein the light emitting element group disposed on the round portion includes:
three first sub-light emitting elements;
three second sub-light emitting elements;
two third sub-light emitting elements; and
four fourth sub-light emitting elements.

10. The display device of claim 8, wherein the light emitting element group disposed on the round portion includes:
three first sub-light emitting elements;
three second sub-light emitting elements;
three third sub-light emitting elements; and
three fourth sub-light emitting elements.

11. The display device of claim 5, wherein the number of the second light emitting elements configuring the light emitting element group disposed on the round portion is greater than the number of the second light emitting elements configuring the light emitting element group disposed on the straight portion.

12. The display device of claim 11, wherein
the number of the second light emitting elements configuring the light emitting element group disposed on the straight portion is sixteen, and
the number of the second light emitting elements configuring the light emitting element group disposed on the round portion is twenty.

13. The display device of claim 12, wherein the light emitting element group disposed on the straight portion includes:
four first sub-light emitting elements;
four second sub-light emitting elements;
four third sub-light emitting elements; and
four fourth sub-light emitting elements.

14. The display device of claim 13, wherein the light emitting element group disposed on the round portion includes:
five first sub-light emitting elements;
five second sub-light emitting elements;
four third sub-light emitting elements; and
six fourth sub-light emitting elements.

15. The display device of claim 13, wherein the light emitting element group disposed on the round portion includes:
five first sub-light emitting elements;
five second sub-light emitting elements;
five third sub-light emitting elements; and
five fourth sub-light emitting elements.

16. The display device of claim 5, wherein
the first sub-light emitting elements disposed in the light emitting element group have a same luminance,
the second sub-light emitting elements disposed in the light emitting element group have a same luminance,
the third sub-light emitting elements disposed in the light emitting element group have a same luminance, and
the fourth sub-light emitting elements disposed in the light emitting element group have a same luminance.

17. The display device of claim 1, wherein the number of the second light emitting elements configuring the light emitting element group disposed on the round portion is different from the number of the second light emitting elements configuring the light emitting element group disposed further inside than the light emitting element group disposed on the round portion.

18. The display device of claim 17, wherein the number of the second light emitting elements configuring the light emitting element group disposed on the round portion is greater than the number of the second light emitting elements configuring the light emitting element group disposed further inside than the light emitting element group disposed on the round portion.

19. The display device of claim 1, further comprising:
a peripheral area surrounding the display area that displays an image, wherein
the display area includes the first display area and the second display area, and
the second display area is disposed between the first display area and the peripheral area.

20. The display device of claim 19, wherein
part of the driving circuit is disposed in the second display area, and
other part of the driving circuit is disposed in the peripheral area.
